(19) United States
(12) Patent Application Publication
(10) Pub. No.: US 2020/0269323 A1
(43) Pub. Date: Aug. 27, 2020

(54) SYNTHESIS OF ULTRA-THIN METAL NANOWIRES USING ORGANIC FREE RADICALS

(71) Applicant: The Regents of the University of California

(72) Inventors: Peidong Yang, Kensington, CA (US); Fan Cui, Berkeley, CA (US); Letian Dou, El Cerrito, CA (US); Zhiqiang Niu, Albany, CA (US)

(73) Assignees: The Regents of the University of California, Oakland, CA (US); The Regents of the University of California, Oakland, CA (US)

(21) Appl. No.: 16/305,387

(22) PCT Filed: May 23, 2017
(86) PCT No.: PCT/US17/34061

§ 371 Date: Nov. 28, 2018

Related U.S. Application Data
(60) Provisional application No. 62/419,127, filed on Nov. 8, 2016.
(60) Provisional application No. 62/344,893, filed on Jun. 2, 2016.

(51) Int. Cl. B22F 9/24; B22F 1/00; H01L 31/0224; H01L 31/18

(52) U.S. Cl. CPC B22F 9/24; B22F 1/0044; H01L 31/022491; B22F 2304/054; B22F 2301/10; B22F 2301/255; H01L 31/1884

(57) ABSTRACT

Provided are methods for synthesizing metal nanowires in solution using an organic reducing agent. A reaction mixture can be provided in solution with a metal salt, the organic reducing agent, and a solvent, where the solvent includes a surface ligand or consists of a surface ligand. The organic reducing agent, such as benzoin, can be decomposed in the reaction mixture to form organic free radicals that reduce metal ions of the metal salt into metal. The surface ligand of the solvent can coordinate with the metal in a manner so that metal nanowires are formed in solution. The diameter and morphology of the nanowires, reaction speed, reaction yield, and other features may be tunable by adjusting parameters such as reaction temperature and chemistry of the reducing agent.

### CROSS-REFERENCE TO RELATED APPLICATIONS

This application claims priority from U.S. Provisional Patent Application 62/344,893, filed Jun. 2, 2016, titled SYNTHESIS OF ULTRA-THIN METAL NANOWIRES USING ORGANIC FREE RADICALS; and from U.S. Provisional Patent Application 62/419,127, filed Nov. 8, 2016, titled SYNTHESIS OF ULTRA-THIN METAL NANOWIRES USING ORGANIC FREE RADICALS; the disclosures of which are incorporated herein by reference in their entirety.

### TECHNICAL FIELD

The present disclosure relates generally to metal nanowires, and more particularly to the synthesis of metal nanowires in solution using organic free radicals as reducing agents.

### BACKGROUND

Transparent conductors have been an important component in numerous electronic devices, such as touch panels, display devices (e.g., LCDs and OLEDs), photovoltaic devices (e.g., solar cells), and electrochromic windows. Current technologies for making transparent conductors using indium tin oxide (ITO) can provide a good tradeoff between optical transparency and electrical sheet resistance. However, ITO suffers from several drawbacks: (1) indium is becoming a scarce and expensive resource; (2) sputtering and patterning (e.g., lithography) are costly; (3) ITO films are brittle and inflexible due to poor mechanical ductility; and (4) ITO films are not transparent in the infrared region, which is not ideal for solar cell and photodetector applications.

Ongoing research and development efforts have been made to find alternative materials that do not suffer from the drawbacks of ITO. Metal nanowires are excellent candidates because they are solution-processable, patternable at a low cost, highly flexible, and transparent in large wavelength ranges. Metal nanowires possess high electrical conductivity, and their optical properties can be tunable according to the size of the metal nanowires. Specifically, increasing the size of the metal nanowires can increase light scattering (haze) and reduce transparency. Ideally, the size of the metal nanowires can be very thin (e.g., less than about 30 nm in diameter), but not too thin to compromise stability and conductivity. Metal nanowires also possess high flexibility and can undergo bending hundreds or thousands of times without compromising their stability and conductivity. This can be useful in the area of flexible electronics and displays.

With excellent electrical properties, tunable optical properties, high flexibility, and solution-processability, there is a growing demand for cost-effective synthesis of metal nanowires.

### SUMMARY

This disclosure pertains to a method of manufacturing metal nanowires. The method includes providing a reaction mixture including a metal salt, an organic reducing agent, and a solvent, where the solvent includes a surface ligand or consists of a surface ligand, activating the reaction mixture to cause the organic reducing agent to decompose into one or more organic free radicals, and reducing metal ions of the metal salt to form metal nanowires in solution.

In some implementations, the organic reducing agent is an aromatic compound. In some implementations, the organic reducing agent includes benzoin. In some implementations, the aromatic compound is substituted with functional groups in the para positions of the aromatic compound. In some implementations, the solvent is a polar or non-polar organic solvent. In some implementations, activating the reaction mixture comprises heating and maintaining the reaction mixture at an elevated temperature, where the elevated temperature is between about 50° C. and about 300° C. In some implementations, the surface ligand is a coordinating small molecule or polymer, such as oleylamine or polyvinylpyrrolidone (PVP). In some implementations, an average diameter of the metal nanowires is between about 2 nm and about 500 nm. In some implementations, an average diameter of the metal nanowires is between about 10 nm and 100 nm, and in various embodiments between about 10 nm and 25 nm, between about 10 nm and 13 nm, between about 12 nm and 18 nm, about 13 nm, about 16 nm, between about 15 nm and 25 nm, between about 20 nm and 40 nm, between about 30 nm and 75 nm, or between about 50 nm and 100 nm. In some implementations, the metal nanowires comprise copper, silver, or gold.

In some implementations, the method of manufacturing metal nanowires includes providing a reaction mixture comprising a metal salt, an organic reducing agent comprising a symmetrical benzoin, and an organic solvent comprising a surface ligand; activating the reaction mixture to cause the organic reducing agent to decompose into one or more organic free radicals; and reducing metal ions of the metal salt to form metal nanowires in solution.

In various such implementations the organic reducing agent can include or be benzoin and/or a symmetrically-di-substituted benzoin, such as a 3,3′(para)-di-substituted benzoin, for example 3,3′-dialkylbenzoin, 3,3′-dialkoxybenzoin, 3,3′-dihalobenzoin and combinations thereof In various such embodiments the one or more free radicals can include or be a benzyl alcohol radical. In various such embodiments activating the reaction mixture can include heating the reaction mixture at an elevated temperature. For example heating and maintaining the reaction mixture at an elevated temperature between about 50° C. and about 300° C.

In various such embodiments the surface ligand of the solvent preferentially bonds to a {100} facet of the metal nanowire in forming the metal nanowire. In various such embodiments the molar ratio of the organic reducing agent to the metal salt is between about 1:2 and about 1:8.

In various such embodiments an average diameter of the metal nanowires is between about 10 nm and 100 nm, and in various embodiments between about 10 nm and 25 nm, between about 10 nm and 13 nm, between about 12 nm and 18 nm, about 13 nm, about 16 nm, between about 15 nm and 25 nm, between about 20 nm and 40 nm, between about 30 nm and 75 nm, or between about 50 nm and 100 nm.

In various such embodiments the length of the metal nanowires is between 1 and 100 um, for example between 2 and 20 um.

In various such embodiments the metal nanowires include copper, silver or gold.

In various such embodiments the metal salt is a copper salt, for example is CuCl₂, the solvent comprising the surface ligand is oleylamine, and the activation is heat.

In various such embodiments the metal salt is a silver salt, for example AgNO₃, the solvent is ethylene glycol comprising the surface ligand PVP, and the activation is heat.

In various such embodiments the metal salt is a gold salt, such as HAuCl₄, the solvent comprising the surface ligand is oleylamine, and the activation is heat.

In some implementations, a transparent conducting electrode or a photovoltaic device comprising metal nanowires formed by any of the preceding methods is provided.

These and other embodiments are described further below with reference to the figures.

### BRIEF DESCRIPTION OF THE DRAWINGS

FIGS. 1A and 1B show transmission electron microscopy (TEM) images at different magnification of copper nanowires synthesized using benzoin in solution and heated to 185° C.

FIGS. 2A and 2B show TEM images of copper nanowires synthesized at different temperatures.

FIGS. 3A-3E show images of five different reducing agents modified by different functional groups, for synthesizing copper nanowires using.

FIGS. 4A and 4B show TEM images of silver nanowires synthesized using benzoin in solution.

FIG. 4C shows a TEM image of gold nanowires synthesized using benzoin in solution.

FIG. 5 shows a cross-section of an example optoelectronic device with an active layer sandwiched between two metal nanowire films.

### DETAILED DESCRIPTION

In the following description, numerous specific details are set forth in order to provide a thorough understanding of the presented concepts. The presented concepts may be practiced without some or all of these specific details. In other instances, well known process operations have not been described in detail so as to not unnecessarily obscure the described concepts. While some concepts will be described in conjunction with the specific embodiments, it will be understood that these embodiments are not intended to be limiting.

Nanowires can differ from their bulk counterparts in that the properties of the nanowires correlate with their size, shape, and morphology. Controlling the size, shape, and morphology of metal nanowires during synthesis can be important in tailoring their properties. For example, in making transparent conducting electrodes, it is desirable to form metal nanowires that are thin enough to minimize light scattering, but thick enough to not compromise electrical conductivity and to ensure stability.

Metal nanowires can be synthesized based on colloidal chemistry. The resulting network of metal nanowires produced in solution can be incorporated in a variety of applications, such as optoelectronic devices. Producing the metal nanowires in solution can have the advantage of lower cost and easier mass production over the production of other materials like ITO. Different handles for tunability, such as reaction conditions and reaction chemistries, can control the size, shape, and morphology of the metal nanowires, thereby tailoring their physical and chemical properties.

Within this description, the terms “nanowires,” “nanorods,” “nanowhiskers,” and “nanopillars” and other similar terms may be used synonymously, except as otherwise indicated. Generally, these terms refer to elongate structures which have lengths and widths, where the length is defined by the longest axis of the structure and the width is defined by the axis generally normal to the longest axis of the structures, and wherein the elongate nanostructures have an aspect ratio greater than one (i.e., length >width in the ratio length: width).

In various embodiments, the diameter of, for example, a “rod” or “wire” is about 1-70 nm, about 1.2-60 nm, about 1.3-50 nm, about 1.5-40 nm, about 2-30 nm, about 2.5-25 nm, about 3-23 nm, about 10-22 nm, about 17-21 nm, about 1-10 nm, about 1-5 nm, about 1 nm, about 1.5 nm, about 2 nm, about 2.5 nm, about 3 nm, about 3.5 nm, about 4 nm, about 4.5 nm, about 5 nm, about 10 nm, about 15 nm, about 16 nm, about 17 nm, about 18 nm, about 19 nm, about 20 nm, about 21 nm, about 22 nm, about 23 nm, about 24 nm, about 25 nm, about 30 nm, about 35 nm, about 40 nm, about 50 nm, or about 60 nm. The diameter for a copper nanowire is typically about 15-25 nm, about 18 nm, about 19 nm, about 20 nm, about 21 nm, or about 22 nm. The length of the “rod” or “wife” is about 50-100 nm, about 80-500 nm, about 100 nm to 1 μm, about 200 nm to 2 μm, about 300 nm to 3 μm, about 400 nm to 4μm, about 500 nm to 5 μm, about 600 nm to 6 μm, about 700 nm to 7 μm, about 800 nm to 8 μm, about 900 nm to 9 μm, about 1 μm to 10 μm, about 2μm to 15 pm, about 3 μm to 20 μm, about 5 μm to 50 μm. For a metal elongated nanostructure, (e.g., a copper nanowire), the length will typically be at least 50 nm, at least 60 nm, at least 70 nm, at least 80 nm, at least 90 nm, at least 100 nm, at least 200 nm, at least 500 nm, at least 1 μm, at least 5 μm, at least 10 μm, or at least 15 μm. In various embodiments an average diameter of copper, silver or gold metal nanowires is between about 10 nm and 100 nm, and in various embodiments between about 10 nm and 25 nm, between about 10 nm and 13 nm, between about 12 nm and 18 nm, about 13 nm, about 16 nm, between about 15 nm and 25 nm, between about 20 nm and 40 nm, between about 30 nm and 75 nm, or between about 50 nm and 100 nm.

The term “aspect ratio” as used herein refers to the ratio of a structure's length to its width. Hence, the aspect ratios of the elongated structures of the disclosure will be greater than one (i.e., length>diameter). In a particular embodiment, the aspect ratio, for example, a “rod” or “wire” is greater than 1, greater than 10, greater than 100, greater than 200, greater than 300, greater than 400, greater than 500, greater than 600, greater than 700, greater than 800, greater than 900, greater than 1,000, greater than 1,500, greater than 2,000, or greater than 5,000. The aspect ratio for a copper nanowire is typically greater than 100, greater than 200, greater than 300, greater than 400, greater than 500, greater than 600, or greater than 700.

Metal nanowires have been synthesized in solution using a silane-based reducing agent. This is described in PCT Patent Application No. WO/2016/049430, titled “Methods to Produce Ultra-Thin Metal Nanowires for Transparent Conductors,” to Yang et al., filed Sep. 25, 2015, which is incorporated herein by reference in its entirety and for all purposes. While the production of metal nanowires using a silane-based reducing agent may achieve some of the advantages described above, the silane-based reducing agent may be expensive, difficult to manufacture, and unstable in air. More specifically, the process for generating silane-based reducing agents in large quantities may be expensive and may dangerously generate hydrogen gas as a byproduct. The choices of workable silanes may be limited, which may leave small room for reactivity selection. Moreover, the reaction time for silane-based chemistry can be long and energy consuming. Finding alternatives that do not suffer from such drawbacks and still provide ultra-thin metal nanowires in solution can be challenging.

The present disclosure relates to forming metal nanowires in solution using an organic reducing agent. The organic reducing agent can be broken down into organic free radicals for reducing metal ions to metal without being quenched by the solvent. The organic reducing agent can be broken down into organic free radicals within suitable temperature ranges (e.g. 50° C. to 300° C.). That way, breaking down the organic reducing agent does not simultaneously melt or otherwise degrade the metal nanowires. The organic reducing agent may be compatible in hydrophilic and hydrophobic solvent systems so that the organic reducing agent may be implemented in different material systems, including copper, silver, and gold. The reaction chemistry and conditions can be adjusted with the organic reducing agent to influence the size of the nanowires, reaction yield, and rate of reaction. In addition, the organic reducing agent is capable of forming metal nanowires having an ultra-thin diameter, such as between about 15 nm and about 25 nm. Achieving such ultra-thin diameters may facilitate production of low-haze transparent conducting electrodes.

Organic reducing agents with the aforementioned properties may be composed of cyclic hydrocarbons. In some implementations, the organic reducing agent is an aromatic compound. The aromatic compound may provide stability for the reducing agent in the solvent system, including in hydrophilic and hydrophobic solvent systems. Examples of aromatic compounds include but are not limited to benzene and pyridine. In some implementations, the aromatic compound of the organic reducing agent may include at least two phenyl groups. In some implementations, one or more functional groups may be between the at least two phenyl groups. Such functional groups may include, for example, hydroxyl groups and ketones. The cyclic hydrocarbons may be bonded to each other so that when the bonds are broken, the cyclic hydrocarbons are separated into free radicals. In some implementations, the free radicals may include benzoyl radicals and/or benzyl (benzyl alcohol) radicals. At least one of the free radicals may participate in the reaction for reducing metal ions to metal to ultimately form the metal nanowires in solution.

In some implementations, each cyclic hydrocarbon can be substituted with a functional group. These functional groups are not attached between the aromatic molecules of the organic reducing agent, but may be symmetrically arranged (e.g., substituted in the para positions of an aromatic compound) about the organic reducing agent. Examples of functional groups can include halogens (e.g., fluorine, chlorine), C1 to C20 alkyl groups, alkoxy groups, etc. As discussed below, modification of the aromatic compound with functional groups can affect the reactivity and rate of reaction of the reducing agent.

In some implementations, the organic reducing agent is benzoin. Benzoin includes a hydroxyl group and a ketone group attached to each other and attached between two phenyl groups. The chemical structure of benzoin is reproduced below.

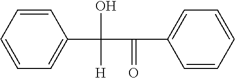 [SMILES: O=C(c1ccccc1)C(O)c1ccccc1]

Benzoin can be produced relatively cheaply and can be decomposed into free radicals at temperatures that do not melt or otherwise degrade the metal nanowires. For example, benzoin can be decomposed by exposure to light or heat, where the temperature for decomposing benzoin can be less than about 200° C. Homolysis of benzoin generates free radicals that are capable of producing ultra-thin metal nanowires and that are stable in different solvent systems. For example, benzoin forms stable free radicals in solvent systems that can include ethylene glycol, oleylamine, hexanes, and alcohols. This allows benzoin to be used as a reducing agent to synthesize copper, silver, gold, and other metal nanowires, because synthesizing different nanowires may require different solvents. When benzoin is activated, such as by exposure to light or heat, benzoin decomposes into a benzyl (benzyl alcohol) radical and a benzoyl radical, which are reproduced below. Without being limited by any theory, the benzyl (benzyl alcohol) radical may participate as the electron donor in the reduction reaction to form metal nanowires.

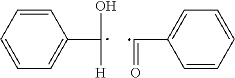

Depending on the metal of the metal nanowire being synthesized, the organic reducing agent is mixed with an appropriate solvent for the metal nanowire being synthesized. The solvent can include, for example, a polar or non-polar organic medium. Examples of polar solvents can include ethanol, butanol, benzyl alcohol, ethylene glycol, diethylene glycol, acetone, methyl ethyl ketone, or a mixture of any of the foregoing. Ethanol, butanol, benzyl alcohol, ethylene glycol, and diethylene glycol are examples of protic polar solvents, and acetone and methyl ethyl ketone are examples of non-protic polar solvents. Examples of non-polar organic solvents can include hexane, toluene, pentane, cyclopentane, cyclohexane, 1,4-dioxane, chloroform, diethyl ether, or a mixture of any of the foregoing.

In some implementations, the solvent includes a surface ligand. Surface ligands may also be referred to as “capping agents.” Surface ligands control the morphology and size of the resulting metal nanowires. As metal nanowires grow in solution, crystallographic facets are formed along paths that minimize surface energies. Surface ligands preferentially bond with certain facets of the crystal structure, making some crystallographic facets more thermodynamically favorable, thereby helping to define the growth and shape of the metal nanowire. In some implementations, the surface ligand of the solvent can preferentially bond with the {100} facet of the metal nanowire. This can allow tips of the metal nanowire to be exposed so that the nanowire can be extended from its tips, resulting in elongation of the nanowire. By way of an example, the amine group from oleylamine can preferentially bond with the {100} facet of a copper nanowire. By way of another example, oxygen atoms from PVP can preferentially bond with the {100} facet of a silver nanowire.

In some implementations, the surface ligand also functions as the solvent for a system. For example, oleylamine may be used as a surface ligand and as a solvent in synthesizing copper nanowires. In some implementations, the surface ligand is combined with a polar or non-polar organic solvent. In synthesizing silver nanowires, for example, PVP may be combined with a polar organic solvent, such as ethylene glycol. In synthesizing gold nanowires, for example, oleylamine may be combined with a non-polar organic solvent, such as hexane.

In the methods disclosed herein, the synthesis reaction includes a metal-containing precursor compound, typically a metal salt. Any number of metal salts are compatible with the methods disclosed herein, including copper-based salts, like Cu(I)I, Cu(I)Br, Cu(I)Cl, Cu(I)F, Cu(I)SCN, Cu(II)Cl₂, Cu(II)Br₂, Cu(II)F₂, Cu(II)OH₂, Cu(II)D-gluconate, Cu(II)MoO₄, Cu(II)(NO₃)₂, Cu(II)(ClO₄)₂, Cu(II)P₂O₇, Cu(II)SeO₃, Cu(II)SO₄, Cu(II)tartrate, Cu(II)(BF₄)₂, Cu(II)(NH₃)₄SO₄, and any hydrates of the foregoing; gold-based salts, like Au(I)I, Au(I)Cl, Au(III)Cl₃, HAu(III)Cl₄, Au(III)Br₃, HAu(III)Br₄, Au(III)OH₃, K(Au(III)CL₄) and any hydrates of the foregoing; silver-based salts, like Ag(I)BrO₃, Ag₂(I)CO₃, Ag(I)ClO₃, Ag(I)Cl, Ag₂(I)CrO₄, Ag(I)citrate, Ag(I)OCN, Ag(I)CN, Ag(I)cyclohexanebutyrate, Ag(I)F, Ag(II)F₂, Ag(I)lactate, Ag(I)NO₃, Ag(I)NO₂, Ag(I)ClO₄, Ag₃(I)PO₄, Ag(I)BF₄, Ag₂(I)SO₄, Ag(I)SCN, and any hydrates of the foregoing; aluminum-based salts, like AlI₃, AlBr₃, AlCl₃, AlF₃, Al(OH)₃, Al-lactate, Al(PO₃)₃, AlO₄P, AL₂(SO₄)₃, and any hydrates of the foregoing; zinc-based salts, like ZnI₂, ZnBr₂, ZnCl₂, ZnF₂, Zn(CN)₂, ZnSiF₆, ZnC₂O₄, Zn(ClO₄)₂, Zn₃(PO₄)₂, ZnSeO₃, ZnSO₄, Zn(BF₄)₂, and any hydrates of the foregoing; nickel-based salts, like NiI₂, NiBr₂, NiCl₂, NiF₂, (NH₄)₂Ni(SO₄)₂, Ni(OCOCH₃)₂, NiCO₃, NiSO₄, NiC₂O₄, Ni(ClO₄)₂, Ni(SO₃NH₂)₂, K₂Ni(H₂IO₆)₂, K₂Ni(CN)₄, and any hydrates of the foregoing; and platinum-based salts, like Pt(II)Br₂, Pt(II)Cl₂, Pt(II)(CN)₂, Pt(II)I₂, Pt(II)(NH₃)₂Cl₂, Pt(IV)Cl₄, H₂Pt(IV)(OH)₆, H₂Pt(IV)Br₆, Pt(IV)(NH₃)₂CL₄, and including any hydrates of the foregoing, where (I) indicates a +1 oxidation state, (II) indicates a +2 oxidation state, (III) indicates a +3 oxidation state, and (IV) indicates a +4 oxidation state, respectively, for the metal ion.

A reaction mixture can be formed including a metal salt, an organic reducing agent, and a solvent having a surface ligand. The organic reducing agent is activated, such as by light or heat, to decompose into one or more free radicals. Metal ions of the metal salt are reduced to form metal nanowires in solution. After forming the metal nanowires in solution, the metal nanowires can be harvested, such as by centrifugation and washing. In some implementations, a network of metal nanowires can be incorporated in a film to form a conducting film. The conducting film can be incorporated in various electronic devices, such as display devices and photovoltaic devices.

By way of example, copper nanowires can be synthesized using benzoin as the organic reducing agent, copper chloride as the metal salt, and oleylamine as the solvent and surface ligand. Upon application of heat, the benzoin can decompose into a benzyl (benzyl alcohol) radical and benzoyl radical. The radicals can serve as electron donors for reducing copper (II) ions in solution. In particular, the benzyl (benzyl alcohol) radical may participate as the electron donor in the reduction reaction to form metal nanowires. As the copper (II) ions are reduced to copper, oleylamine can coordinate with the copper to control the growth and growth of the copper into copper nanowires. Such a reaction scheme is illustrated below.

$${CuCl}_{2} {{\to }_{Oleylamine}}^{ Benzoin \text{/} Heat } copper nanowires$$

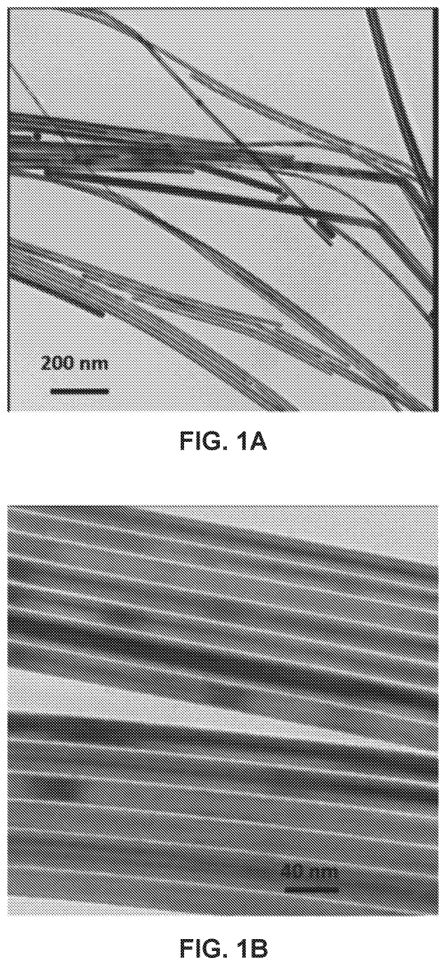

FIGS. 1A and 1B show transmission electron microscopy (TEM) images at different magnification of copper nanowires synthesized using benzoin in solution and heated to 185° C. 85 mg of CuCl₂.H₂O (0.5 mmol) and 5 g of oleylamine are mixed in a reaction vessel. The reaction mixture is sonicated at room temperature until it becomes a clear blue solution. Then, 0.424 g of benzoin is added to solution. The reaction mixture is degassed and purged with nitrogen at 70° C. for 30 minutes. Then, the reaction temperature is raised to 120° C. under nitrogen atmosphere and kept for around 20 minutes until the color of the solution reaches clear yellow. Next, the reaction temperature is raised to 185° C. and allowed to stay for 3 hours until the reaction is complete. The product is harvested at 8000 rpm for 5 minutes. Then, the nanowires are washed with toluene, and then with toluene/isopropanol (1:1) three times to remove excess oleylamine and benzoin for further characterization. The morphologies of resulting product are examined by transmission electron microscopy (TEM, Hitachi H7650). As shown in FIGS. 1A and 1B, the resulting product shows uniform nanowires with minimum amount of nanoparticles. The uniform copper nanowires have a length of up to about 10 μm, and a diameter of about 18±2 nm.

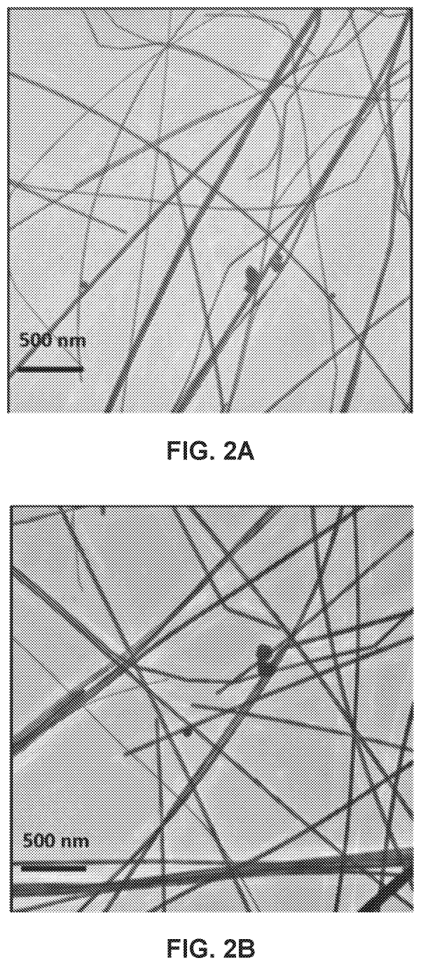

The diameter, shape, and length of metal nanowires can be varied by modifying reaction conditions. In some implementations, the diameter of the metal nanowires can be varied by changing the reaction temperature. Reaction yield and rate of reaction can also be varied by changing the reaction temperature. It can be shown that as reaction temperature increases, an average diameter of the metal nanowires decreases. FIGS. 2A and 2B show TEM images of copper nanowires synthesized at different temperatures. The average nanowire diameter is about 18 nm with a reaction temperature of 185° C. as shown in FIGS. 1A and 1B. The average nanowire diameter increases to about 20 nm with a reaction temperature of about 180° C. as shown in FIG. 2A, and further increases to about 33 nm with a reaction temperature of about 165° C. Without being limited by any theory, the diameter control may be explained in terms of nucleation. At higher temperature, the reduction of metal ion is faster and leads to a faster nucleation. Faster nucleation can mean more nucleation sites at the same time, and more nucleation sites forming can imply smaller volumes for each and every nucleation site, which later will grow into thinner nanowires.

While higher reaction temperatures may facilitate growth of thinner nanowires, reaction temperatures that are too high may melt or otherwise degrade the nanowires. In some implementations, a reaction mixture is heated and maintained at an elevated temperature, where the elevated temperature is between about 50° C. and 300° C., or between about 100° C. and 200° C.

The reducing power of the organic reducing agent can be modified by decorating the organic reducing agent with different functional groups. As discussed above, the aromatic compound of the organic reducing agent can include substituted functional groups. The substituted functional groups can be symmetrically arranged (e.g., substituted in the para positions of the aromatic compound) about the organic reducing agent so that the organic reducing agent can be cleaved evenly. If the functional groups are not positioned symmetrically, there would be a shift in electronegativity and free radicals may not be produced. Thus, in the case of benzoin derivatives, functional groups can be decorated symmetrically on both sides of benzoin.

The functional groups can be characterized by their electronegativity (more electron-withdrawing) and their electropositivity (more electron-donating). The reducing power of the organic reducing agent can be enhanced by adding a more electropositive functional group to the aromatic compound. This can speed up the reaction in forming metal nanowires. However, if a more electronegative functional group is added to the aromatic compound, the reducing power of the organic reducing agent is lowered due to reduced electron negativity at the radical spot.

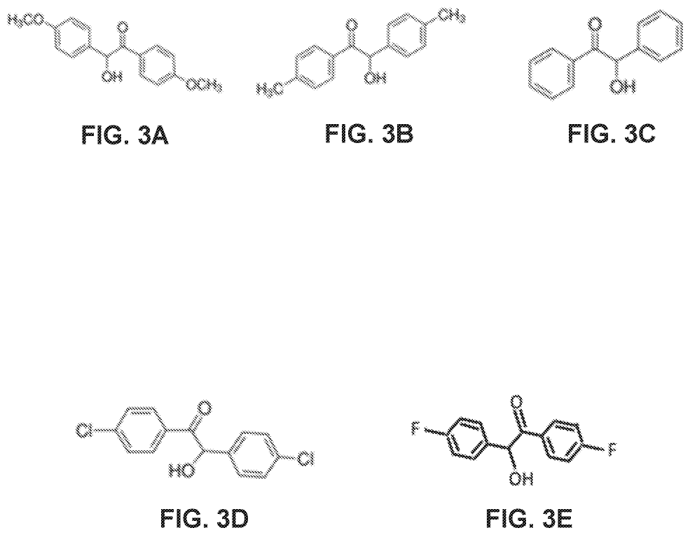

The relationship between the rate of reaction of reducing agents with different functional groups was determined for five different reactions for synthesizing copper nanowires using benzoin symmetrically modified by different functional groups shown in FIGS. 3A-3E. Each reaction held constant the reaction temperature, the reaction time, and the molar ratio between the metal salt and the reducing agent. FIG. 3A shows 3,3′-dimethylbenzoin as the reducing agent, FIG. 3B shows 3,3′-dimethoxybenzoin as the reducing agent, FIG. 3C shows benzoin as the reducing agent, FIG. 3D shows 3,3′-dichlorobenzoin as the reducing agent, and FIG. 3E shows 3,3′-difluorobenzoin as the reducing agent. The benzoin derivative with the methoxy functional groups corresponded to the fastest among the five reactions, as the methoxy functional group possessed the strongest electron-donating group. As the functional groups became more electron-withdrawing, however, the reaction rate became slower.

The reaction yield can also be affected by the different functional groups. The yields of copper nanowire products were measured to be 94.0%, 65.3%, 31.3%, 2.5%, and 0% for reactions with 3,3′-dimethylbenzoin, 3,3′-dimethoxybenzoin, benzoin, 3,3′-dichlorobenzoin, and 3,3′-difluorobenzoin, respectively. Thus, more electron-withdrawing groups can slow down a reaction and reduce reaction yield, even to the point of no reaction happening at all.

Tuning the rate of reaction and reaction yield with different functional groups can open up more possibilities for producing metal nanowires of different metals. A more reactive organic reducing agent may not only produce a faster reaction, but may also facilitate reaction with more inert metal ions. So metal nanowires other than copper nanowires may be formed by increasing the reactivity of the organic reducing agent, even if the metal ions of such metal nanowires are less active than copper ions.

Furthermore, different functional groups can add more flexibility in tuning the rate of reaction alongside reaction temperature. What this means is that reaction temperature is not the only handle for tuning the rate of reaction. As discussed earlier, increased reaction temperatures can lead to higher yield, faster reactions, and smaller nanowire diameters. However, if the temperature is too high, this can melt or otherwise degrade the metal nanowires. Thus, different functional groups provide another handle for tunability for improving rate of reaction and reaction yield. If, for example, copper nanowires are synthesized at over 200° C. to achieve a desirable yield and rate of reaction but such high temperatures start melting the copper nanowires, then the copper nanowires can be synthesized at a lower temperature while still achieving the desirable yield and rate of reaction. This can occur if the organic reducing agent is modified with more electropositive functional groups.

In addition to selection of different functional groups and adjusting reaction temperature, another handle for tuning the rate of reaction and reaction yield can be the molar ratio of the reducing agent to the metal salt. A greater concentration of reducing agent can lead to a faster reaction and a higher yield. However, too much reducing agent and a faster reaction can generate a larger ratio of undesirable nanoparticles in the reaction. In some implementations, the molar ratio between the organic reducing agent and the metal salt can be between about 1:1 to 1:30, or between about 1:2 to 1:8, or about 1:4.

In some implementations, the reaction time can be maintained at a particular reaction temperature for as little as a few minutes to more than 24 hours. More time can allow for more product formation. In some implementations, the reaction mixture can be held at a particular reaction temperature anywhere between about 1 hour and about 24 hours.

The organic reducing agent can be generalized to different metal systems, including copper, silver, and gold. For example, benzoin can be used not only as a reducing agent for producing copper nanowires as discussed above with FIGS. 1A and 1B, but benzoin can be used as a reducing agent for producing silver nanowires as well as gold nanowires.

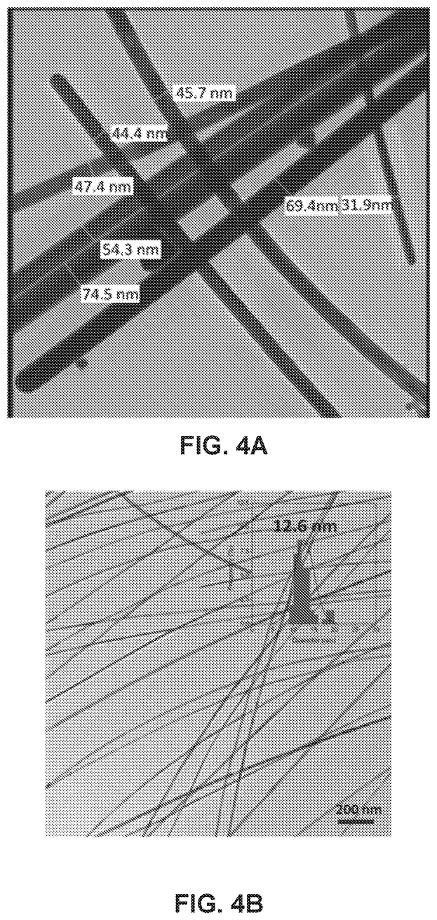

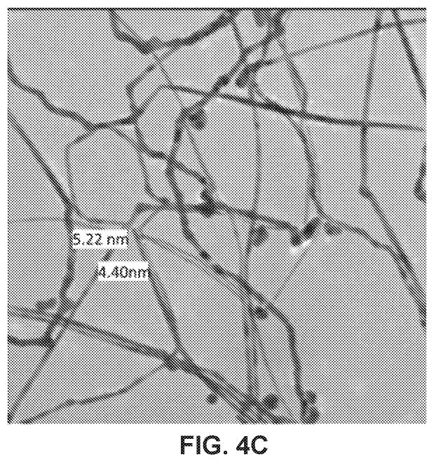

FIG. 4A shows a TEM image of silver nanowires synthesized using benzoin in solution. PVP, silver nitrate (AgNO₃), and benzoin are dissolved in ethylene glycol, and then heated up to about 130 to 150° C. for several hours. Silver nanowires are synthesized, where an average diameter of the silver nanowires can be tuned by changing reaction temperature, concentration of the PVP, and adding halogen anions. In one specific example, silver nanowires were synthesized by combining 0.15 M polyvinylpyrrolidone (PVP, MW about 55 000) and 0.1 M AgNO₃ solution in ethylene glycol. Benzoin (2 mmol) was dissolved in ethylene glycol and the solution purged with N₂ to remove oxygen. Then, the benzoin solution was slowly heated up to 130° C. under argon protection. A 3 mL aliquot of PVP solution and 3 mL of AgNO₃ solution were simultaneously injected in a dropwise fashion. Next, the reactants were left to react for 10 min before being ramped up to 150° C. where the mixture was left for an extra hour. The product was harvested by centrifuging, and it was washed 3 times with isopropyl alcohol. The resulting nanowires had diameters of about 30 to 75 nm and aspect ratios of about 500 nm.

In other specific examples the addition of halide salts to the reaction solution resulted in the formation of even thinner silver nanowires. For example, 45 mg AgNO₃, from 0 to about 2.45 mg NaCl, from 2.25 to about 6.75 mg NaBr, and from about 40 to 70 mg polyvinylpyrrolidone (PVP, MW about 1 300 000) were dissolved in 10 mL ethylene glycol and stirring at room temperature for 30 min. At least 500 mg benzoin was added into the reaction solution. Suitable molar ratio ranges of reagents for thin silver nanowire synthesis are AgNO₃ (silver salt):PVP:NaCl (chloride salt): NaBr (bromide salt):benzoin are 1:(1.4˜2.4):(0˜0.16):(0.083˜0.25):>7. The mixture was heated from about room temperature to about 150 to 170° C., for example 150° C. or 160° C., for about 15 min with N₂ gas bubbling through the reaction solution. The N₂ bubbling was stopped when the reaction reached the desired temperature. The reaction mixture was left undisturbed for 1 hour and cooled down to room temperature. The resulting silver nanowires were collected by adding acetone into the product dispersion. Depending on the growth temperature and the type amount of halide anions used, the nanowires had average diameters ranging from, for example about 20 to 40 nm when a combination of Cl and Br salts were used, or 12 nm to 18 nm when a Br salt alone was used. The aspect ratio of the nanowires was about 1000 to 3000. A specific example is 45 mg AgNO₃, 6.3 mg NaBr, 45 mg polyvinylpyrrolidone (PVP, MW about 1 300 000) and 500 mg benzoin heated to about 160° C. resulting in silver nanowires about 12 nm in diameter and about 10 μm long, as show in the a TEM image of the resulting silver nanowires in FIG. 4B.

FIG. 4C shows a TEM image of gold nanowires synthesized using benzoin in solution. Oleylamine, chloroauric acid (HAuCl₄), and benzoin are dissolved in hexanes, and then the mixture is left at room temperature for five hours. Gold nanowires are synthesized as a result. In one specific example, gold nanowires were synthesized by combining 0.3 mg of oleylamine, 22 mg of HAuCl₄, and 8.77 mg of benzoin were dissolved in 13 g of hexanes under vigorous stirring. After the solution was clear, the mixture was left undisturbed at room temperature for 5 h. The product was collected by centrifuging and washed 3 times with toluene.

As discussed above, the diameter and morphology of the nanowires, reaction speed, reaction yield, and other features may be tunable by adjusting parameters such as reaction temperature and the chemistry of the reducing agent. For example, smaller nanowires can be synthesized at higher temperatures. Smaller nanowires can be useful minimizing light scattering in some optoelectronic devices, such as in display devices. In some implementations, an average diameter of the metal nanowires can be between about 15 nm and about 25 nm. Larger nanowires can be useful in maximizing light scattering so that there can be greater absorption of light in some optoelectronic devices, such as in photovoltaic devices. In some implementations, an average diameter of the metal nanowires can be between about 50 nm and about 100 nm.

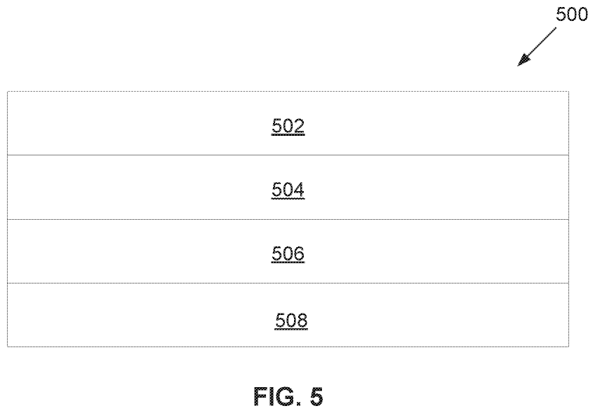

FIG. 5 shows a cross-section of an example of an optoelectronic device 500 including an active layer 504 that is sandwiched between two metal nanowire films 502 and 506, disposed on a glass substrate 508.

It is also well known that length of nanowires is important for achieving electrical percolation. Without being bound by theory, it is well understood that a minimum length is required to achieve low sheet resistance in films at a given metal content. The length of nanowires can be between 2 and 20 um and more likely around 10 um. Under some reaction condition the length can be as high as 50-100 um for increased optical transmission and lower haze and scattering. This is desired for some display device applications.

Additional disclosure, providing detail with respect to some specific embodiments and contextual information, is provided in the appended documents.

Although illustrative embodiments and applications are shown and described herein, many variations and modifications are possible which remain within the concept, scope, and spirit of the disclosure, and these variations would become clear to those of ordinary skill in the art after perusal of this application. Accordingly, the present embodiments are to be considered as illustrative and not restrictive, and the scope of the disclosure is not to be limited to the details given herein, but may be modified within the scope and equivalents of the appended claims.

1-18. (canceled)

19. A method of manufacturing metal nanowires, comprising:
providing a reaction mixture comprising a metal salt, an organic reducing agent comprising a symmetrical benzoin, and an organic solvent comprising a surface ligand;
activating the reaction mixture to cause the organic reducing agent to decompose into one or more organic free radicals; and
reducing metal ions of the metal salt to form metal nanowires in solution.

20. The method of claim 19, wherein the organic reducing agent comprises benzoin.

21. The method of claim 19, wherein the organic reducing agent comprises symmetrically-di-substituted benzoins.

22. The method of claim 19, wherein the organic reducing agent is selected from the group consisting of benzoin, symmetrically-di-substituted benzoins and combinations thereof.

23. The method of claim 22, wherein the organic reducing agent is benzoin.

24. The method of claim 22, wherein the organic reducing agent is a symmetrically-di-substituted benzoin.

25. The method of claim 24, wherein the symmetrically-di-substituted benzoin is a 3,3′(para)-di-substituted benzoin.

26. The method of claim 22, wherein the organic reducing agent is selected from the group consisting of 3,3′-dialkylbenzoin, 3,3′-dialkoxybenzoin, 3,3′-dihalobenzoin and combinations thereof.

27. The method of claim 19, wherein the one or more free radicals comprises a benzyl alcohol radical.

28. (canceled)

29. The method of claim 19, wherein activating the reaction mixture comprises heating and maintaining the reaction mixture at an elevated temperature; between about 50° C. and about 300° C.

30. (canceled)

31. The method of claim 19, wherein a molar ratio of the organic reducing agent to the metal salt is between about 1:2 and about 1:8.

32-35. (canceled)

36. The method of claim 19, wherein the metal nanowires comprise a metal selected from the group consisting of copper, silver and gold.

37. The method of claim 36, wherein the metal nanowires are copper nanowires, the metal salt is a copper salt, the solvent comprising the surface ligand is oleylamine, and the activation is heat.

38. The method of claim 37, wherein the copper salt is CuCl₂.

39. The method of claim 36, wherein the metal nanowires are silver nanowires, the metal salt is a silver salt, the solvent is ethylene glycol comprising the surface ligand PVP, and the activation is heat.

40. The method of claim 39, wherein the silver salt is AgNO₃.

41-45. (canceled)

46. The method of claim 36, wherein the metal nano s are gold nanowires, the metal salt is a gold salt, the solvent comprising the surface ligand is oleylamine, and the activation is heat

47. The method of claim 46, the gold salt HAuCL₄.

48. (canceled)

49. A transparent conducting electrode comprising metal nanowires formed by the method recited in claim 19.

50. A photovoltaic device comprising metal nanowires formed by the method recited in claim 19.
